(19) United States
(12) Patent Application Publication
(10) Pub. No.: US 2025/0054762 A1
(43) Pub. Date: Feb. 13, 2025

(54) METHOD FOR MANUFACTURING DISASSEMBLABLE SUBSTRATES

(71) Applicants: COMMISSARIAT A L'ENERGIE ATOMIQUE ET AUX ENERGIES ALTERNATIVES, Paris (FR); SOITEC, Bernin (FR)

(72) Inventors: Thierry SALVETAT, Grenoble (FR); Guillaume BERRE, Grenoble (FR); François- Xavier DARRAS, Apprieu (FR)

(73) Assignees: COMMISSARIAT A L'ENERGIE ATOMIQUE ET AUX ENERGIES ALTERNATIVES, Paris (FR); SOITEC, Bernin (FR)

(21) Appl. No.: 18/722,778

(22) PCT Filed: Dec. 19, 2022
(86) PCT No.: PCT/EP2022/086785

§ 371 Date: Jun. 21, 2024

(30) Foreign Application Priority Data
Dec. 24, 2021 (FR) 2114488
Feb. 21, 2022 (FR) 2201495

(51) Int. Cl. H01L 21/265; H01L 21/304; H01L 21/324; H01L 23/00

(52) U.S. Cl. CPC H01L 21/265; H01L 21/304; H01L 21/324; H01L 24/80; H01L 2224/80896

(57) ABSTRACT

A method for manufacturing disassemblable substrates, comprising: (a) providing a first substrate comprising implanted species forming a flat implantation zone and a proximal surface; a second substrate comprising a surface; (b) forming a series of cavities on the proximal surface of the first substrate and/or on the surface of the second substrate; (c) assembling the first and second substrates (1, 2) by direct bonding; and (d) applying a heat treatment to weaken the flat implantation zone. Further, the series of cavities being arranged in such a way as to allow direct bonding between the first and second substrates during step (c); and prevent thermal initiation of the splitting of the weakened flat implantation zone at the end of step (d).

### TECHNICAL FIELD

The invention relates to the technical field of manufacturing of disassemblable substrates. These are also referred to as temporary handles.

The invention is notably of interest for the transfer of a useful layer onto a carrier substrate for the manufacture of a device (or component) for all types of applications (electronic, mechanical, optical, etc.).

### PRIOR ART

There are mainly two types of temporary handles in the prior art. A first type of temporary handle is based on a polymer material, and is only compatible with low temperatures (typically below 300° C.). A second type of temporary handle is compatible with higher temperatures (typically around 500° C. to 600° C.). Temporary handles known from the prior art are conventionally manufactured with the aid of a weakened bonding interface between two substrates. The weakened bonding interface may be obtained with rough surfaces, or with the materials of the two substrates selected so as to be physicochemically not very compatible. The two substrates can be subsequently disassembled by means of a heat treatment, or mechanically by inserting a blade along the bonding interface.

Such prior art solutions are not entirely satisfactory, as their implementation is complex.

### DISCLOSURE OF THE INVENTION

The invention aims to overcome all or some of the aforementioned drawbacks. To this end, the subject matter of the invention is a method for manufacturing disassemblable substrates, comprising the steps of:
a) providing:
   a first substrate, comprising implanted species forming a flat implantation zone, the first substrate comprising a surface proximal to the flat implantation zone;
   a second substrate, comprising a surface;
b) forming a series of cavities on the proximal surface of the first substrate and/or on the surface of the second substrate;
c) assembling the first and second substrates by direct bonding between the proximal surface of the first substrate and the surface of the second substrate;
d) applying a heat treatment to the assembly obtained at the end of step c), according to a thermal budget adapted to weaken the flat implantation zone;
   the series of cavities being arranged during step b) in such a way as to:
   allow direct bonding between the first and second substrates during step c);
   prevent thermal initiation of the splitting of the weakened flat implantation zone at the end of step d).

Thus, such a method according to the invention makes it possible to obtain temporary handles by using a flat implantation zone formed by implanted species, then weakened by a heat treatment so as to subsequently disassemble the first and second substrates by the application of a mechanical stress (e.g. insertion of a blade at the bonding interface). The heat treatment of step d) makes it possible to mature the implanted defects, which can generate defects such as microcracks or blisters which will grow and thereby weaken the flat implantation zone.

The arrangement (for example the dimensioning and/or distribution) of the series of cavities on the proximal surface of the first substrate and/or on the surface of the second substrate during step b) is adapted to delimit, at the end of step c):
bonding zones, facing the walls separating the cavities and occupying the inter-cavity space, the bonding zones therefore being subject to a stiffening effect;
free zones, facing the cavities.

More specifically, the series of cavities is arranged on the proximal surface of the first substrate and/or on the surface of the second substrate during step b) such that:
the bonding zones have a surface area adapted to allow direct bonding between the first and second substrates during step c);
the free zones have a spatial distribution adapted to prevent thermal initiation of the splitting of the weakened flat implantation zone at the end of step d).

Triggering of the splitting of the flat implantation zone is mainly due to the maturation of microcrack type defects. The maturation of microcrack type defects is linked to the implanted species (conventionally ionized gaseous species) undergoing a heat treatment (for example at 500° C. for several tens of minutes), in the presence of a stiffening effect. The inventors noted that the presence of the cavities in the free zones, adjacent to the bonding zones, limited the development of microcracks in the bonding regions.

Furthermore, when the cavities extend on the proximal surface of the first substrate, short of the flat implantation zone, the free zones are not subject to a stiffening effect, and can therefore deform inside the cavity or cavities facing them during the maturation of blister type defects. The maturation of blister type defects is in fact linked to the implanted species (conventionally ionized gaseous species) undergoing a heat treatment (for example at 500° C. for several tens of minutes), in the absence of a stiffening effect. The growth of blister type defects is limited by the phenomenon of exfoliation corresponding to their decapsulation. The presence of cavities allows vertical expansion of the blister type defects.

The flat implantation zone thus withstands the thermal energy provided by the heat treatment of step d), that is to say the flat implantation zone is not split by the heat treatment of step d), but is sufficiently weakened (by the presence of microcracks and where appropriate blisters) to be split subsequently by mechanical stress so as to disassemble the first and second substrates, for example by inserting a blade between the first and second substrates or by peeling.

The method according to the invention may include one or more of the following features.

According to one feature of the invention, the method comprises a step e) consisting in carrying out mechanical splitting of the weakened flat implantation zone after step d), so as to disassemble the first and second substrates.

This affords an advantage in terms of simple disassembly of the first and second substrates, for example by inserting a blade between the first and second substrates.

According to a feature of the invention, the series of cavities is arranged during step b) such that each pair of adjacent cavities is spaced apart by a distance between:
a first threshold, above which direct bonding between the first and second substrates is allowed during step c);
a second threshold, strictly greater than the first threshold, below which thermal initiation of the splitting of the weakened flat implantation zone is prevented at the end of step d).

This affords an advantage in terms of obtaining:
(i) bonding zones having a sufficient surface area to allow direct bonding between the first and second substrates during step c);
(ii) free zones, arranged between the bonding zones to prevent thermal initiation of the splitting of the weakened flat implantation zone at the end of step d).

According to a feature of the invention, the first threshold is between 500 nm and 3 μm, preferably between 1 μm and 2 μm.

According to a feature of the invention, the second threshold is between 5 μm and 200 μm, preferably between 5 μm and 100 μm, more preferably between 5 μm and 10 μm.

According to a feature of the invention, the first and second substrates have a bonding surface at the end of step c); and the series of cavities is arranged during step b) in such a way as to occupy between 50% and 85% of the bonding surface, preferably between 60% and 80% of the bonding surface.

This affords an advantage in terms of obtaining:
(i) bonding zones having a sufficient surface area to allow direct bonding between the first and second substrates during step c);
(ii) free zones, arranged between the bonding zones to prevent thermal initiation of the splitting of the weakened flat implantation zone at the end of step d).

According to a feature of the invention:
the series of cavities is formed during step b) on the proximal surface of the first substrate in such a way as to extend short of the flat implantation zone;
the series of cavities is arranged during step b) in such a way that each cavity has at least one dimension, in the plane of the proximal surface of the first substrate, less than or equal to twice a predetermined average radius of exfoliation, preferably less than or equal to twice a predetermined minimum radius of exfoliation.

This affords an advantage in terms of limiting the lateral expansion of the blisters inside the cavities in order to prevent exfoliation.

According to a feature of the invention:
the series of cavities is formed during step b) on the surface of the second substrate;
the series of cavities is arranged during step b) in such a way that each cavity has at least one dimension, in the plane of the surface of the second substrate, less than or equal to twice a predetermined average radius of exfoliation, preferably less than or equal to twice a predetermined minimum radius of exfoliation.

This affords an advantage in terms of limiting the lateral expansion of the blisters inside the cavities in order to prevent exfoliation.

According to a feature of the invention:
the series of cavities is formed during step b):
   on the proximal surface of the first substrate in such a way as to extend short of the flat implantation zone, and on the surface of the second substrate;
the series of cavities is arranged during step b) in such a way that each cavity has at least one dimension, in the plane of the proximal surface of the first substrate and in the plane of the surface of the second substrate, less than or equal to twice a predetermined average radius of exfoliation, preferably less than or equal to twice a predetermined minimum radius of exfoliation.

This affords an advantage in terms of limiting the lateral expansion of the blisters inside the cavities in order to prevent exfoliation.

According to a feature of the invention, the series of cavities is formed during step b) on the proximal surface of the first substrate in such a way as to extend beyond the flat implantation zone.

This affords an advantage in terms of eliminating the presence of blisters, which allows greater tolerance on the lateral dimension of the cavities in the plane of the proximal surface of the first substrate. The series of cavities is arranged to prevent the lateral propagation of microcracks and thereby the splitting of the weakened flat implantation zone.

According to a feature of the invention, each cavity of the series occupies the proximal surface of the first substrate and/or the surface of the second substrate in such a way as to delimit an opening having a shape selected from a rectangular, square, triangular or circular shape.

According to a feature of the invention, the thermal budget of step d) is defined by:
a heat treatment temperature of between 200° C. and 900° C.,
a duration of the heat treatment of between a few minutes and a few tens of minutes.

This affords an advantage in terms of obtaining a flat implantation zone able to withstand the thermal energy provided by a heat treatment for splitting or by a heat treatment for reinforcing the bonding interface. The flat implantation zone is not split by such a thermal budget, but is sufficiently weakened (by the presence of microcracks and blisters) to be split subsequently by mechanical stress so as to disassemble the first and second substrates, for example by inserting a blade between the first and second substrates. Such a thermal budget would be sufficient to split the flat implantation zone in the absence of such a series of cavities on the proximal surface of the first substrate and/or on the surface of the second substrate.

According to a feature of the invention, step a) comprises a preliminary step consisting in determining an average radius of exfoliation and/or a minimum radius of exfoliation by a statistical analysis of microscopic observations, after having applied to the first substrate a heat treatment for splitting the flat implantation zone.

This heat treatment is applied directly to the first substrate to determine the radius of exfoliation in the case where the cavities are formed on the surface of the second substrate. If the cavities are formed on the proximal surface of the first substrate, this heat treatment will be applied to the first substrate after thinning over its entire surface and over a thickness corresponding to the depth of the cavities.

This affords an advantage in terms of improving the reliability of the dimensioning of the cavities during step b) in order to obtain free zones, not subject to a stiffening effect, which can deform inside the cavity or cavities facing them during the maturation of blister type defects during step d), while limiting the lateral expansion of the blisters inside the cavities in order to prevent exfoliation.

According to a feature of the invention, the first substrate provided in step a) is made of a material selected from:
a semiconductor material, preferably selected from Si, Ge, Si—Ge, SiC, a III-V material;
lithium tantalate LiTaO₃, lithium niobate LiNbO₃.

The invention also relates to an assembly for manufacturing disassemblable substrates, comprising:
a first substrate, comprising implanted species forming a flat implantation zone, the first substrate comprising a surface proximal to the flat implantation zone;
a second substrate, comprising a surface;
a series of cavities, arranged on the proximal surface of the first substrate and/or on the surface of the second substrate in such a way as to:
   allow direct bonding between the proximal surface of the first substrate and the surface of the second substrate;
   prevent thermal initiation of the splitting of the flat implantation zone, after a heat treatment applied to the first and second bonded substrates, according to a thermal budget adapted to weaken the flat implantation zone.

Thus, as stated above, the arrangement (for example the dimensioning and/or distribution) of the series of cavities on the proximal surface of the first substrate and/or on the surface of the second substrate is adapted to delimit:
bonding zones, facing the walls separating the cavities and occupying the inter-cavity space, the bonding zones therefore being subject to a stiffening effect;
free zones, facing the cavities.

More specifically, the series of cavities is arranged on the proximal surface of the first substrate and/or on the surface of the second substrate such that:
the bonding zones have a surface area adapted to allow direct bonding between the first and second substrates;
the free zones have a spatial distribution adapted to prevent thermal initiation of the splitting of the weakened flat implantation zone after the heat treatment applied to the first and second bonded substrates.

Triggering of the splitting of the flat implantation zone is mainly due to the maturation of microcrack type defects. The maturation of microcrack type defects is linked to the implanted species (conventionally ionized gaseous species) undergoing a heat treatment (for example at 500° C. for several tens of minutes), in the presence of a stiffening effect. The inventors noted that the presence of the cavities in the free zones, adjacent to the bonding zones, limited the development of microcracks in the bonding regions.

Furthermore, when the cavities extend on the proximal surface of the first substrate, short of the flat implantation zone, the free zones are not subject to a stiffening effect, and can therefore deform inside the cavity or cavities facing them during the maturation of blister type defects. The maturation of blister type defects is in fact linked to the implanted species (conventionally ionized gaseous species) undergoing a heat treatment (for example at 500° C. for several tens of minutes), in the absence of a stiffening effect. The growth of blister type defects is limited by the phenomenon of exfoliation corresponding to their decapsulation. The presence of cavities allows vertical expansion of the blister type defects.

The flat implantation zone thus withstands the thermal energy provided by the heat treatment applied to the first and second bonded substrates, that is to say the flat implantation zone is not split by the heat treatment, but is sufficiently weakened (by the presence of microcracks and where appropriate blisters) to be split subsequently by mechanical stress so as to disassemble the first and second substrates, for example by inserting a blade between the first and second substrates or by peeling.

According to a feature of the invention, the series of cavities is arranged on the proximal surface of the first substrate and/or on the surface of the second substrate such that each pair of adjacent cavities is spaced apart by a distance between:
a first threshold, above which direct bonding between the first and second substrates is allowed;
a second threshold, strictly greater than the first threshold, below which thermal initiation of the splitting of the flat implantation zone is prevented after the heat treatment applied to the first and second bonded substrates.

This affords an advantage in terms of obtaining:
(i) bonding zones having a sufficient surface area to allow direct bonding between the first and second substrates;
(ii) free zones, arranged between the bonding zones to prevent thermal initiation of the splitting of the weakened flat implantation zone after the heat treatment applied to the first and second bonded substrates.

According to a feature of the invention, the first and second substrates are intended to have a bonding surface; and the series of cavities is arranged on the proximal surface of the first substrate and/or on the surface of the second substrate in such a way as to occupy between 50% and 85% of the bonding surface, preferably between 60% and 80% of the bonding surface.

This affords an advantage in terms of obtaining:
(i) bonding zones having a sufficient surface area to allow direct bonding between the first and second substrates;
(ii) free zones, arranged between the bonding zones to prevent thermal initiation of the splitting of the weakened flat implantation zone after the heat treatment applied to the first and second bonded substrates.

According to a feature of the invention:
the series of cavities is arranged on the proximal surface of the first substrate in such a way as to extend short of the flat implantation zone;
the series of cavities is arranged on the proximal surface of the first substrate in such a way that each cavity has at least one dimension, in the plane of the proximal surface of the first substrate, less than or equal to twice a predetermined average radius of exfoliation, preferably less than or equal to twice a predetermined minimum radius of exfoliation.

This affords an advantage in terms of limiting the lateral expansion of the blisters inside the cavities in order to prevent exfoliation.

According to a feature of the invention, the series of cavities is arranged on the surface of the second substrate in such a way that each cavity has at least one dimension, in the plane of the surface of the second substrate, less than or equal to twice a predetermined average radius of exfoliation, preferably less than or equal to twice a predetermined minimum radius of exfoliation.

This affords an advantage in terms of limiting the lateral expansion of the blisters inside the cavities in order to prevent exfoliation.

According to a feature of the invention:
the series of cavities is arranged:
   on the proximal surface of the first substrate in such a way as to extend short of the flat implantation zone, and
   on the surface of the second substrate,
the series of cavities is arranged in such a way that each cavity has at least one dimension, in the plane of the proximal surface of the first substrate and in the plane of the surface of the second substrate, less than or equal to twice a predetermined average radius of exfoliation, preferably less than or equal to twice a predetermined minimum radius of exfoliation.

This affords an advantage in terms of limiting the lateral expansion of the blisters inside the cavities in order to prevent exfoliation.

According to a feature of the invention, the series of cavities is arranged on the proximal surface of the first substrate in such a way as to extend beyond the flat implantation zone.

This affords an advantage in terms of eliminating the presence of blisters, which allows greater tolerance on the lateral dimension of the cavities in the plane of the proximal surface of the first substrate. The series of cavities is arranged to prevent the lateral propagation of microcracks and thereby the splitting of the weakened flat implantation zone.

### Definitions

“Substrate” means a self-supporting physical carrier, made of a base material from which it is possible to form a device (or component) for all types of applications, notably electronic, mechanical, optical. A substrate may be a “wafer”, which generally takes the form of a disk obtained by cutting from an ingot of crystalline material.

“Flat zone” means flatness within the usual tolerances linked to experimental manufacturing conditions, and not perfect flatness in the mathematical sense of the term.

“Radius of exfoliation” means a parameter, denoted R_{exfo}, defined by the equation:

$${R}_{exfo} = \frac{64}{3} \times \frac{1 - {v}^{2}}{{Ek}_{B} T} \times \frac{1}{α \times D} \times {σ}^{2} \times {e}^{2}$$

wherein “v” designates the Poisson's ratio of the thin layer, “E” designates the Young's modulus of the thin layer, “kB” is the Boltzmann constant, “T” is the temperature (in K) to which the thin layer is subjected, “a” is the effective dose fraction (in %) of the implanted species, “D” is the implanted dose (in at./cm²) of the species, “a” is the limiting shear stress, “e” is the thickness of the thin layer, and “x” is the multiplication operator. The thin layer is the part of the first substrate extending between the flat implantation zone and the surface of the first substrate through which the implantation of the species took place (surface proximal to the flat implantation zone). Exfoliation corresponds to (local) partial detachment of the thin layer in the flat implantation zone. It is difficult to theoretically determine the radius of exfoliation owing to physical quantities that are difficult to quantify, notably the limiting shear stress. The radius of exfoliation is specific to the implantation carried out in the first substrate.

“Average radius of exfoliation” means an arithmetic average of the radii of exfoliation obtained experimentally.

“Predetermined” means that the average radius of exfoliation is determined before the design of the series of cavities formed on the proximal surface of the first substrate and/or on the surface of the second substrate.

The term “cavity” designates a superficial, open cavity, extending on the proximal surface of the first substrate and/or on the surface of the second substrate, and which may be obtained by etching.

“Distributed on the surface” means a spatial distribution of the series of cavities on the proximal surface of the first substrate and/or on the surface of the second substrate.

“Direct bonding” means bonding (preferably spontaneous) resulting from direct contact between two surfaces, that is to say in the absence of an additional element such as a glue, a wax or a solder. Adhesion arises mainly from van der Waals forces resulting from the electronic interaction between the atoms or molecules of two surfaces, from hydrogen bonds due to surface preparations or from covalent bonds established between the two surfaces. Direct bonding is advantageously carried out at ambient temperature and pressure. Direct bonding can cover thermocompression bonding or eutectic bonding depending on the nature of the two surfaces brought into contact.

“Thermal initiation” means initiation of the splitting of the flat implantation zone obtained by thermal energy.

“Mechanical splitting” means splitting of the (weakened) flat implantation zone obtained by mechanical energy.

“Allow direct bonding” means that the bonding interface (limited primarily by all the surfaces of the walls separating the cavities) has sufficient adhesion energy to bond the first and second substrates together.

“Prevent thermal initiation” means that thermal energy (for example provided by a heat treatment applied to the assembly of the first and second substrates) is not sufficient to initiate splitting of the flat implantation zone which would have the effect of separating the first and second substrates.

“Type III-V material” means a binary alloy between elements located respectively in column III and in column V of the periodic table of the elements.

“Semiconductor material” means a material having an electrical conductivity at 300 K of between 10⁻⁸ S/cm and 10³ S/cm.

The expression “occupy a percentage of the bonding surface” by the series of cavities can be described by an occupation rate defined by the formula (a+b)²−a²/(a+b)², where each cavity delimits an opening having a square shape of side “a”, each pair of adjacent cavities being spaced apart by a distance “b” on the proximal surface of the first substrate and/or on the surface of the second substrate.

“Thermal budget” means a supply of energy of a thermal nature, determined by the selection of a value for the temperature of the heat treatment and the selection of a value for the duration of the heat treatment.

X and Y values expressed using the expressions “between X and Y” or “comprised between X and Y” are included in the defined range of values.

“Facing” means that an element A faces an element B when the elements A and B are opposite one another along the normal to the bonding surface of the first and second substrates.

“Extending short of” means that the cavities extend short of the flat implantation zone when the depth of the cavities is strictly less than the implantation depth of the implanted species.

“Extending beyond” means that the cavities extend beyond the flat implantation zone when the depth of the cavities is strictly greater than the implantation depth of the implanted species.

### BRIEF DESCRIPTION OF THE DRAWINGS

Further features and advantages will emerge from the detailed disclosure of various embodiments of the invention, the disclosure being accompanied by examples and references to the attached drawings.

FIG. 1 is a schematic sectional view, depicting the first and second substrates before bonding according to a first embodiment in which the series of cavities is formed on the surface of the second substrate.

FIG. 2 is a schematic sectional view, depicting the direct bonding of the first and second substrates according to the first embodiment.

FIG. 3 is a schematic sectional view, depicting the presence of blister type defects after bonding of the first and second substrates according to the first embodiment, when the assembly undergoes a heat treatment leading to maturation of the defects.

FIG. 4 is a schematic sectional view, depicting the insertion of a blade at the bonding interface to disassemble the first and second substrates according to the first embodiment.

FIG. 5 is a graph showing, on the abscissa, the implantation depth (in μm) and, on the ordinate, a radius of exfoliation (in μm) obtained experimentally.

FIG. 6 is an illustration of a microscopic observation of localized tears (or exfoliations) of the surface of the first substrate (i.e. the surface proximal to the flat implantation zone), the first substrate being subjected to a splitting heat treatment without a stiffening effect.

FIG. 7 is a schematic sectional view, depicting the first and second substrates before bonding according to a second embodiment in which the series of cavities is formed on the proximal surface of the first substrate.

FIG. 8 is a schematic sectional view, depicting the first and second substrates before bonding according to a third embodiment in which the series of cavities is formed on the proximal surface of the first substrate and on the surface of the second substrate.

FIG. 9 is a schematic sectional view, depicting the first and second substrates before bonding according to a fourth embodiment in which the series of cavities is formed on the proximal surface of the first substrate in such a way as to extend beyond the flat implantation zone.

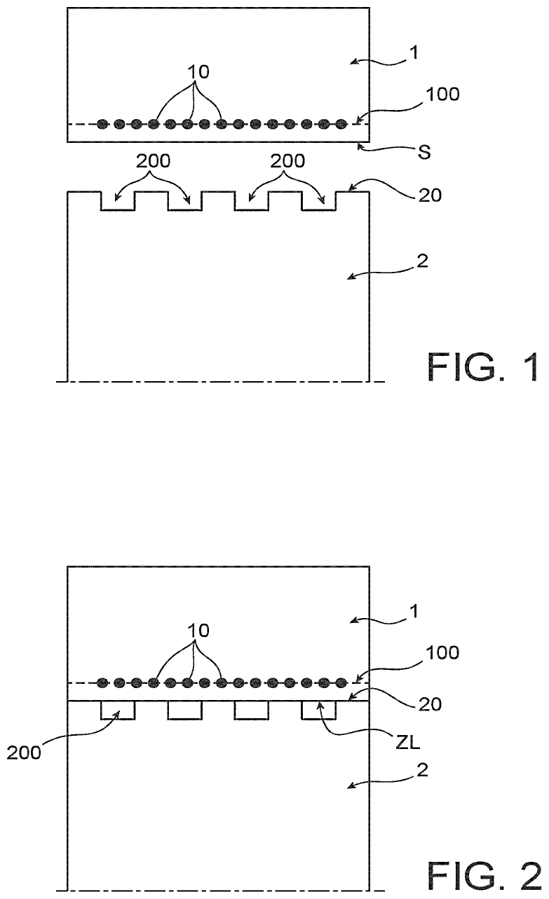

Note that FIGS. 1 to 4 and 7 to 9 described above are schematic, and are not drawn to scale for the sake of readability and to simplify understanding thereof. The sections are along the normal to the bonding surface.

### DETAILED DESCRIPTION OF THE EMBODIMENTS

Identical elements or elements performing the same function will be designated by the same references in the various embodiments, for the sake of simplification.

### Manufacturing Method

The invention relates to a method for manufacturing disassemblable substrates 1, 2, comprising the steps of:
a) providing:
   a first substrate 1, comprising implanted species 10 forming a flat implantation zone 100, the first substrate 1 comprising a surface S proximal to the flat implantation zone 100;
   a second substrate 2, comprising a surface 20;
b) forming a series of cavities 200 on the proximal surface S of the first substrate 1 and/or on the surface 20 of the second substrate 2;
c) assembling the first and second substrates 1, 2 by direct bonding between the proximal surface S of the first substrate 1 and the surface 20 of the second substrate 2;
d) applying a heat treatment to the assembly obtained at the end of step c), according to a thermal budget adapted to weaken the flat implantation zone 100; the series of cavities 200 being arranged during step b) in such a way as to:
   allow direct bonding between the first and second substrates 1, 2 during step c);
   prevent thermal initiation of the splitting of the weakened flat implantation zone 100 at the end of step d).

### Step a)

Step a) is depicted in FIGS. 1 and 7 to 9.

The implanted species 10 are advantageously gaseous species, preferably comprising ionized hydrogen atoms and/or ionized helium atoms. It is possible to carry out co-implantation between these species and/or with other gaseous species, or to carry out multi-implantation of the same gaseous species.

The first substrate 1 provided in step a) is advantageously made of a material selected from:
a semiconductor material, preferably selected from Si, Ge, Si—Ge, SiC, a III-V material;
lithium tantalate LiTaO₃, lithium niobate LiNbO₃.

By way of non-limiting example, when the first substrate 1 is made of silicon, it is possible to implant ionized hydrogen atoms according to the following parameters:
an energy between 120 keV and 200 keV;
a dose between 6·10¹⁶ at·cm⁻² and 7·10¹⁶ at·cm⁻².

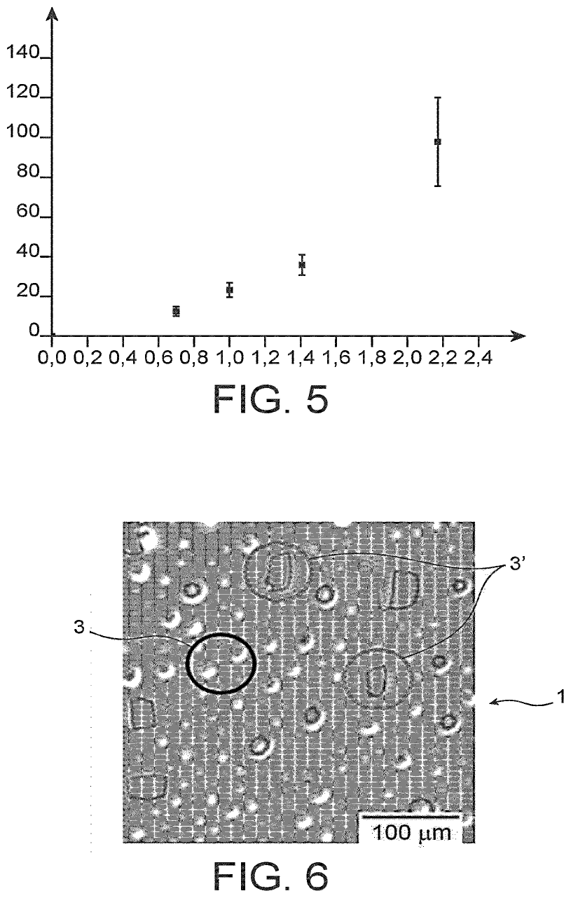

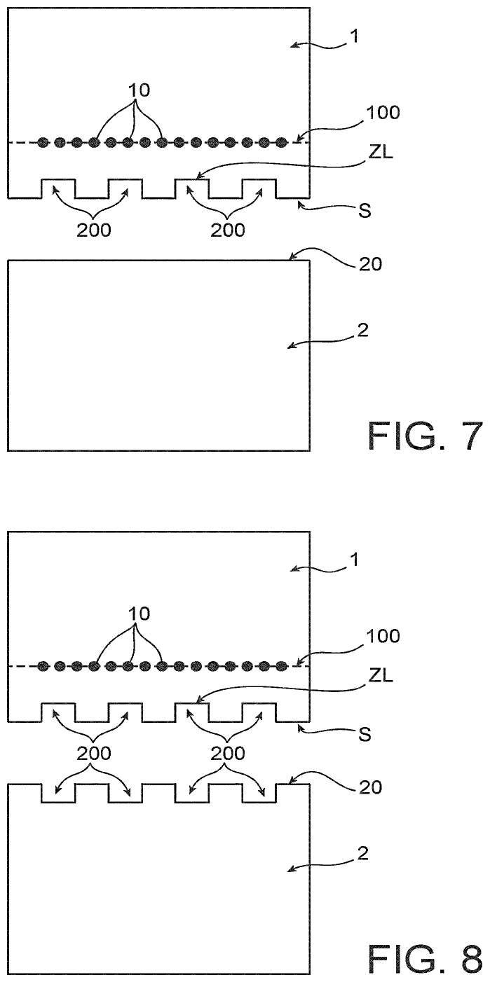

As depicted in FIGS. 5 and 6, step a) advantageously comprises a preliminary step consisting in determining an average radius of exfoliation and/or a minimum radius of exfoliation by a statistical analysis of microscopic observations, after having applied to the first substrate 1 (comprising the implanted species 10) a heat treatment for splitting the flat implantation zone 100 (for example 1 h at 500° C. when the first substrate 1 is made of silicon). This heat treatment is applied directly to the first substrate 1 to determine the radius of exfoliation in the case where the cavities 200 are formed on the surface 20 of the second substrate 2. If the cavities 200 are formed on the proximal surface S of the first substrate 1, this heat treatment will be applied to the first substrate 1 after thinning over its entire surface and over a thickness corresponding to the depth of the cavities 200.

The heat treatment for splitting the flat implantation zone 100 is carried out according to a thermal budget similar to the thermal budget of step d). In the absence of a stiffening effect, this heat treatment leads to the formation of blisters 3 and localized tears 3′ (exfoliations). As depicted in FIG. 6, optical microscopy observations of the surface S (proximal to the flat implantation zone 100) of the first substrate 1 make it possible to see these blisters 3 and these exfoliations 3′, the exfoliations 3′ being easily identifiable by the presence of a dark border around their outline. Image analysis makes it possible to measure the surface area of these exfoliations 3′. The surface areas thus measured are converted into radii (considering the defects to be circular). The dimensions thus extracted, in sufficient number to allow a statistical analysis (i.e. typically a population of several tens of exfoliations), then make it possible to define their minimum, average, and maximum size. FIG. 5 shows in this regard the radius of the exfoliations 3′ observed according to this experimental protocol for silicon first substrates 1, implanted at a fixed dose, as a function of the implantation energy here translated into implantation depth.

### Step b)

Step b) is depicted in FIGS. 1 and 7 to 9.

According to a first embodiment depicted in FIG. 1, the series of cavities 200 is formed during step b) on the surface 20 of the second substrate 2. The series of cavities 200 is dimensioned and distributed during step b) in such a way as to:
allow direct bonding between the first and second substrates 1, 2 during step c);
prevent thermal initiation of the splitting of the weakened flat implantation zone 100 at the end of step d).

According to a second embodiment depicted in FIG. 7, the series of cavities 200 is formed during step b) on the proximal surface S of the first substrate 1 in such a way as to extend short of the flat implantation zone 100. Step b) is performed after the formation of the flat implantation zone 100. The series of cavities 200 is dimensioned and distributed during step b) in such a way as to:
allow direct bonding between the first and second substrates 1, 2 during step c);
prevent thermal initiation of the splitting of the weakened flat implantation zone 100 at the end of step d).

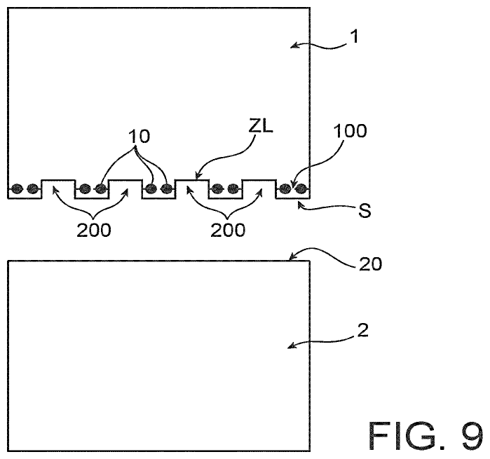

According to a third embodiment depicted in FIG. 8, the series of cavities 200 is formed during step b) on the proximal surface S of the first substrate 1, in such a way as to extend short of the flat implantation zone 100, and on the surface 20 of the second substrate 2. Step b) is performed after the formation of the flat implantation zone 100. The series of cavities 200 is dimensioned and distributed during step b) in such a way as to:
allow direct bonding between the first and second substrates 1, 2 during step c);
prevent thermal initiation of the splitting of the weakened flat implantation zone 100 at the end of step d).

According to a fourth embodiment depicted in FIG. 9, the series of cavities 200 is formed during step b) on the proximal surface S of the first substrate 1 in such a way as to extend beyond the flat implantation zone 100. Step b) is performed after the formation of the flat implantation zone 100. The series of cavities 200 is spaced apart during step b) in such a way as to:
allow direct bonding between the first and second substrates 1, 2 during step c);
prevent thermal initiation of the splitting of the weakened flat implantation zone 100 at the end of step d).

The series of cavities 200 is advantageously arranged during step b) such that each pair of adjacent cavities 200 is spaced apart by a distance between:
a first threshold, above which direct bonding between the first and second substrates 1, 2 is allowed during step c);
a second threshold, strictly greater than the first threshold, below which thermal initiation of the splitting of the weakened flat implantation zone 100 is prevented at the end of step d).

The first threshold is advantageously between 500 nm and 3 μm, preferably between 1 μm and 2 μm. The second threshold is advantageously between 5 μm and 200 μm, preferably between 5 μm and 100 μm, more preferably between 5 μm and 10 μm.

The first and second substrates 1, 2 have a bonding surface at the end of step c). The series of cavities 200 is advantageously arranged during step b) in such a way as to occupy between 50% and 85% of the bonding surface, preferably between 60% and 80% of the bonding surface.

The series of cavities 200 is advantageously arranged during step b) in such a way that each cavity 200 has at least one dimension, in the plane of the proximal surface S of the first substrate 1, and/or in the plane of the surface 20 of the second substrate 2, less than or equal to twice the predetermined average radius of exfoliation, preferably less than or equal to twice the predetermined minimum radius of exfoliation. According to the first embodiment depicted in FIG. 1, the lateral dimension of the cavities 200 is in the plane of the surface 20 of the second substrate 2. According to the second embodiment depicted in FIG. 7, the lateral dimension of the cavities 200 is in the plane of the proximal surface S of the first substrate 1. According to the third embodiment depicted in FIG. 8, the lateral dimension of the cavities 200 is in the plane of the proximal surface S of the first substrate 1 and in the plane of the surface 20 of the second substrate 2. According to the fourth embodiment depicted in FIG. 9, the lateral dimension of the cavities, in the plane of the proximal surface S of the first substrate 1, is not a critical parameter in the absence of blisters 3.

Each cavity 200 of the series occupies the proximal surface S of the first substrate 1 and/or the surface 20 of the second substrate 2 in such a way as to delimit an opening having a shape advantageously selected from a rectangular, square, triangular or circular shape. By way of non-limiting example, each cavity 200 may delimit an opening having a square shape, each side of which is between 10 μm and 30 μm, preferably between 15 μm and 20 μm. If the predetermined minimum radius of exfoliation is 15 μm, the cavities 200 may advantageously take the form of squares with a side of 30 μm, circles with a diameter of 30 μm, or lines with a width of 30 μm.

The cavities 200 may be obtained by etching the second substrate 2. By way of non-limiting example, the second substrate 2 may be made of a semiconductor material, such as silicon.

In the presence of blisters 3, the series of cavities 200 is advantageously dimensioned such that each cavity 200 has a depth, along the normal to the surface 20 of the second substrate 2 (and/or along the normal to the proximal surface S of the first substrate 1), greater than the maximum deflection of the blisters 3, denoted Hₘₐₓ. The value of Hₘₐₓ may be approximated, according to the theory of elasticity of plates and blisters (“Theory of Plates and Shells”) developed by Timoshenko, by the formula:

$${H}_{max} = \frac{3}{16} \times \frac{1 - {v}^{2}}{{Ee}^{3}} \times {P}_{1} \times {R}^{4}$$

wherein:
   “v” designates the Poisson's ratio of the thin layer transferred,
   “E” designates the Young's modulus of the thin layer,
   “e” is the thickness of the thin layer,
   “Pi” is the pressure in a blister 3 (depending on the implantation dose),
   “R” is the radius of a blister 3,
   “x” is the multiplication operator.

The thin layer is the part of the first substrate 1 extending between the flat implantation zone 100 and the surface S of the first substrate 1 through which the implantation of the species 10 has taken place (proximal to the flat implantation zone 100) when the cavities 200 are formed on the surface 20 of the second substrate 2.

However, the depth of each cavity 200 may be less than the maximum deflection of the blisters 3 (i.e. the blisters 3 can ‘touch the bottom of the cavities 200’) without this affecting correct implementation of a method according to the invention.

### Step c)

Step c) is depicted in FIG. 2.

Step c) is advantageously preceded by a step consisting in cleaning the surfaces to be bonded of the first and second substrates 1, 2, for example to avoid contamination of the surfaces by hydrocarbons, particles or metallic elements. As a non-limiting example, it is possible to clean the surfaces to be bonded using a dilute SC1 solution (mixture of NH₄OH and H₂O₂).

Step c) is advantageously preceded by a step consisting in activating the surfaces to be bonded of the first and second substrates 1, 2, for example by plasma treatment or by ion beam sputtering (IBS). Activating the surfaces to be bonded makes it possible to reduce the first threshold.

Step c) is preferably carried out in an environment with a controlled atmosphere. As a non-limiting example, step c) may be carried out under high vacuum such as a secondary vacuum of less than 10⁻² mbar.

### Step d)

The heat treatment is applied to the assembly of the first and second substrates 1, 2 obtained at the end of step c). The heat treatment is applied during step d) according to a thermal budget adapted to weaken the flat implantation zone 100. More specifically, in the first, second and third embodiments depicted respectively in FIGS. 1, 7 and 8, the implanted species 10 generate microcracks or blisters 3 in response to the heat treatment applied during step d), which weaken the flat implantation zone 100. The blisters 3 generated during step d) extend inside the series of cavities 200. One or more blisters 3 may extend inside a cavity 200 of the series. The heat treatment of step d) makes it possible to mature the implanted defects, generating microcracks and blisters 3 which will grow and thereby weaken the flat implantation zone 100.

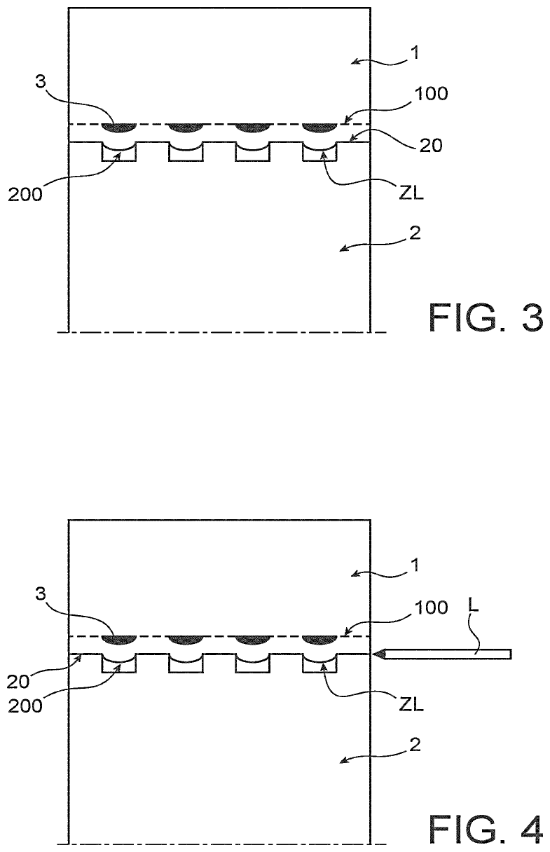

As depicted in FIG. 3, blister 3 type defects appear during step d), when the assembly is subjected to a heat treatment. The free zones ZL, extending at the surface S of the first substrate 1 (i.e. the surface proximal to the flat implantation zone 100), facing the cavities 200, are not subject to a stiffening effect. The free zones ZL, not subject to a stiffening effect, can then deform inside the cavity or cavities 200 facing them, after the maturation of blister 3 type defects, in such a way as to prevent thermal initiation of the splitting of the flat implantation zone 100 weakened at the end of step d). This mechanism is identical for the second and third embodiments depicted respectively in FIGS. 7 and 8. The free zones ZL, extending at the proximal surface S of the first substrate 1, facing the cavities 200, are not subject to a stiffening effect. The free zones ZL, not subject to a stiffening effect, can then deform inside the cavity or cavities 200 facing them, after the maturation of blister 3 type defects, in such a way as to prevent thermal initiation of the splitting of the flat implantation zone 100 weakened at the end of step d).

In the fourth embodiment depicted in FIG. 9, the implanted species 10 only generate microcracks in the bonding zones in response to the heat treatment applied during step d), which weaken the flat implantation zone 100.

The thermal budget of step d) is advantageously adapted to split the flat implantation zone 100, in the absence of the series of cavities 200 on the proximal surface S of the first substrate 1 and/or on the surface 20 of the second substrate 2.

However, according to the invention, that is to say in the presence of such a series of cavities 200 on the proximal surface S of the first substrate and/or on the surface 20 of the second substrate 2, such a thermal budget of step d) weakens the flat implantation zone 100 but does not make it possible to thermally initiate the splitting of the flat implantation zone 100.

By way of non-limiting example, the thermal budget of step d) may be defined by:
a heat treatment temperature of between 200° C. and 900° C.,
a duration of the heat treatment of between a few minutes and a few tens of minutes.

The thermal budget of step d) depends notably on the material of the first substrate 1 and the conditions of implantation of the implanted species 10. When the first substrate 1 is made of silicon Si, the heat treatment temperature may be between 300° C. and 600° C., for example of the order of 500° C. When the first substrate 1 is made of lithium tantalate LiTaO₃, the heat treatment temperature may be of the order of 200° C. When the first substrate 1 is made of indium phosphide InP, the heat treatment temperature may be of the order of 150° C.

The heat treatment of step d) is advantageously thermal annealing.

### Step e)

The method may comprise a step e) consisting in carrying out mechanical splitting of the weakened flat implantation zone 100 after step d), so as to disassemble the first and second substrates 1, 2.

As depicted in FIG. 4, step e) may be carried out by inserting a blade L between the first and second substrates 1, 2, at the bonding interface, from an edge of the assembly of the first and second substrates 1, 2. As a variant, it is possible to laminate a peeling layer (for example made of a polymer material) on the thin layer, which will then be used to mechanically peel the thin layer.

After carrying out step e), the disassembled first substrate 1 may be recycled and reused. In addition, after carrying out step e), the thin layer transferred to the second substrate 2 may be subjected to chemical and/or mechanical treatments to recover a flat surface, and obtain a useful layer from which it is possible to form a component for all types of applications, notably electronic, mechanical, optical.

### Technological Steps

The first substrate 1 and/or the second substrate 2 may be subjected to technological steps, carried out between steps d) and e), in order to form all or part of a component. By way of non-limiting examples, the technological steps may consist of steps of thinning, layer transfer, layer deposition, photolithography, etching, etc. It should be noted that the thinning of the first substrate 1 is advantageously carried out between steps c) and d). The assembly of the first and second substrates 1, 2 may be secured to a receiving substrate for the implementation of certain technological steps.

### Manufacturing Assembly

The invention also relates to an assembly for manufacturing disassemblable substrates 1, 2, comprising:
a first substrate 1, comprising implanted species 10 forming a flat implantation zone 100, the first substrate 1 comprising a surface S proximal to the flat implantation zone 100;
a second substrate 2, comprising a surface 20;
a series of cavities 200, arranged on the proximal surface S of the first substrate 1 and/or on the surface 20 of the second substrate 2 in such a way as to: allow direct bonding between the proximal surface S of the first substrate 1 and the surface 20 of the second substrate 2;
   prevent thermal initiation of the splitting of the flat implantation zone 100 after a heat treatment applied to the first and second bonded substrates 1, 2, according to a thermal budget adapted to weaken the flat implantation zone 100.

The series of cavities 200 is advantageously arranged on the proximal surface S of the first substrate 1 and/or on the surface 20 of the second substrate 2 such that each pair of adjacent cavities 200 is spaced apart by a distance between:
a first threshold, above which direct bonding between the first and second substrates 1, 2 is allowed;
a second threshold, strictly greater than the first threshold, below which thermal initiation of the splitting of the weakened flat implantation zone 100 is prevented after the heat treatment applied to the first and second bonded substrates 1, 2.

The first and second substrates 1, 2 are intended to have a bonding surface. The series of cavities 200 is advantageously arranged on the proximal surface S of the first substrate 1 and/or on the surface 20 of the second substrate 2 in such a way as to occupy between 50% and 85% of the bonding surface, preferably between 60% and 80% of the bonding surface.

The series of cavities 200 is advantageously arranged in such a way that each cavity 200 has at least one dimension, in the plane of the proximal surface S of the first substrate 1 and/or in the plane of the surface 20 of the second substrate 2, less than or equal to twice a predetermined average radius of exfoliation, preferably less than or equal to twice a predetermined minimum radius of exfoliation.

According to the first embodiment depicted in FIG. 1, the lateral dimension of the cavities 200 is in the plane of the surface 20 of the second substrate 2. According to the second embodiment depicted in FIG. 7, the lateral dimension of the cavities 200 is in the plane of the proximal surface S of the first substrate 1. According to the third embodiment depicted in FIG. 8, the lateral dimension of the cavities 200 is in the plane of the proximal surface S of the first substrate 1 and in the plane of the surface 20 of the second substrate 2. According to the fourth embodiment depicted in FIG. 9, the lateral dimension of the cavities, in the plane of the proximal surface S of the first substrate 1, is not a critical parameter in the absence of blisters 3.

According to the first embodiment depicted in FIG. 1, the series of cavities 200 is arranged on the surface 20 of the second substrate 2 in such a way that each cavity 200 has at least one dimension, in the plane of the surface 20 of the second substrate 2, less than or equal to twice a predetermined average radius of exfoliation, preferably less than or equal to twice a predetermined minimum radius of exfoliation.

According to the second embodiment depicted in FIG. 7:
the series of cavities 200 is arranged on the proximal surface S of the first substrate 1 in such a way as to extend short of the flat implantation zone 100;
the series of cavities 200 is arranged on the proximal surface S of the first substrate 1 in such a way that each cavity 200 has at least one dimension, in the plane of the proximal surface S of the first substrate 1, less than or equal to twice a predetermined average radius of exfoliation, preferably less than or equal to twice a predetermined minimum radius of exfoliation.

According to the third embodiment depicted in FIG. 8:
the series of cavities 200 is arranged:
   on the proximal surface S of the first substrate 1 in such a way as to extend short of the flat implantation zone 100, and on the surface 20 of the second substrate 2;
the series of cavities 200 is arranged in such a way that each cavity 200 has at least one dimension, in the plane of the proximal surface S of the first substrate 1 and in the plane of the surface 20 of the second substrate 2, less than or equal to twice a predetermined average radius of exfoliation, preferably less than or equal to twice a predetermined minimum radius of exfoliation.

According to the fourth embodiment depicted in FIG. 9, the series of cavities 200 is arranged on the proximal surface S of the first substrate 1 in such a way as to extend beyond the flat implantation zone 100.

The technical features described above (first and second substrates 1, 2, implanted species 10, average radius of exfoliation, shape of the cavities 200) apply to this subject matter of the invention.

The invention is not limited to the embodiments disclosed. Those skilled in the art are capable of envisaging technically effective combinations thereof, and substituting equivalents therefor.

1. A method for manufacturing disassemblable substrates, the method comprising:
(a) providing a first substrate comprising implanted species forming a flat implantation zone, the first substrate comprising a surface proximal to the flat implantation zone, and a second substrate comprising a surface;
(b) forming a series of cavities on the proximal surface of the first substrate and/or on the surface of the second substrate;
(c) assembling the first and second substrates by direct bonding between the proximal surface of the first substrate and the surface of the second substrate; and
(d) applying a heat treatment to the assembly obtained at the end of step (c), according to a thermal budget adapted to weaken the flat implantation zone,
wherein the series of cavities are arranged during step (b) in such a way as to:
allow direct bonding between the first and second substrates during step (c); and
prevent thermal initiation of the splitting of the weakened flat implantation zone at the end of step (d).

2. The method as claimed in claim 1, further comprising a step (e) of performing mechanical splitting of the weakened flat implantation zone after step (d), so as to disassemble the first and second substrates.

3. The method as claimed in claim 1, wherein the series of cavities is arranged during step (b) such that each pair of adjacent cavities is spaced apart by a distance between:
a first threshold, above which direct bonding between the first and second substrates is allowed during step (c); and
a second threshold, strictly greater than the first threshold, below which thermal initiation of the splitting of the weakened flat implantation zone is prevented at the end of step (d).

4. The method as claimed in claim 3, wherein the first threshold is between 500 nm and 3 μm.

5. The method as claimed in claim 3, wherein the second threshold is between 5 μm and 200 μm.

6. The method as claimed in claim 1, wherein the first and second substrates have a bonding surface at the end of step (c); and the series of cavities is arranged during step (b) in such a way as to occupy between 50% and 85% of the bonding surface.

7. The method as claimed in claim 1, wherein:
the series of cavities is formed during step (b) on the proximal surface of the first substrate in such a way as to extend short of the flat implantation zone;
the series of cavities is arranged during step (b) in such a way that each cavity has at least one dimension, in the plane of the proximal surface of the first substrate, less than or equal to twice a predetermined average radius of exfoliation.

8. The method as claimed in claim 1, wherein:
the series of cavities is formed during step (b) on the surface of the second substrate; and
the series of cavities is arranged during step (b) in such a way that each cavity has at least one dimension, in the plane of the surface of the second substrate, less than or equal to twice a predetermined average radius of exfoliation.

9. The method as claimed in claim 1, wherein:
the series of cavities is formed during step (b):
on the proximal surface of the first substrate in such a way as to extend short of the flat implantation zone, and
on the surface of the second substrate; and
the series of cavities is arranged during step (b) in such a way that each cavity has at least one dimension, in the plane of the proximal surface of the first substrate and in the plane of the surface of the second substrate, less than or equal to twice a predetermined average radius of exfoliation.

10. The method as claimed in claim 1, wherein the series of cavities is formed during step (b) on the proximal surface of the first substrate in such a way as to extend beyond the flat implantation zone.

11. The method as claimed in claim 1, wherein step (a) comprises a preliminary step including determining an average radius of exfoliation and/or a minimum radius of exfoliation by a statistical analysis of microscopic observations, after having applied to the first substrate a heat treatment for splitting the flat implantation zone.

12. An assembly for manufacturing disassemblable substrates, comprising:
a first substrate, comprising implanted species forming a flat implantation zone, the first substrate comprising a surface proximal to the flat implantation zone;
a second substrate, comprising a surface; and
a series of cavities, arranged on the proximal surface of the first substrate and/or on the surface of the second substrate in such a way as to:
allow direct bonding between the proximal surface of the first substrate and the surface of the second substrate; and
prevent thermal initiation of the splitting of the flat implantation zone, after a heat treatment applied to the first and second bonded substrates according to a thermal budget adapted to weaken the flat implantation zone.

13. The assembly as claimed in claim 12, wherein the series of cavities is arranged on the proximal surface of the first substrate and/or on the surface of the second substrate such that each pair of adjacent cavities is spaced apart by a distance between:
a first threshold, above which direct bonding between the first and second substrates is allowed; and
a second threshold, strictly greater than the first threshold, below which thermal initiation of the splitting of the flat implantation zone is prevented after the heat treatment applied to the first and second bonded substrates.

14. The assembly as claimed in claim 12, wherein the first and second substrates are configured to have a bonding surface; and the series of cavities is arranged on the proximal surface of the first substrate and/or on the surface of the second substrate in such a way as to occupy between 50% and 85% of the bonding surface.

15. The assembly as claimed in claim 12, wherein:
the series of cavities is arranged on the proximal surface of the first substrate in such a way as to extend short of the flat implantation zone; and
the series of cavities is arranged on the proximal surface of the first substrate in such a way that each cavity has at least one dimension, in the plane of the proximal surface of the first substrate, less than or equal to twice a predetermined average radius of exfoliation.

16. The assembly as claimed in claim 12, wherein the series of cavities is arranged on the surface of the second substrate in such a way that each cavity has at least one dimension, in the plane of the surface of the second substrate, less than or equal to twice a predetermined average radius of exfoliation.

17. The assembly as claimed in claim 12, wherein:
the series of cavities is arranged:
on the proximal surface of the first substrate in such a way as to extend short of the flat implantation zone, and
on the surface of the second substrate; and
the series of cavities is arranged in such a way that each cavity has at least one dimension, in the plane of the proximal surface of the first substrate and in the plane of the surface of the second substrate, less than or equal to twice a predetermined average radius of exfoliation.

18. The assembly as claimed in claim 12, wherein the series of cavities is arranged on the proximal surface of the first substrate in such a way as to extend beyond the flat implantation zone.
